(19) United States
(12) Patent Application Publication
(10) Pub. No.: US 2024/0412990 A1
(43) Pub. Date: Dec. 12, 2024

(54) SUBSTITUTE SMOKING CONSUMABLE

(71) Applicant: NERUDIA LIMITED, Speke (GB)

(72) Inventors: Chris LORD, Liverpool (GB); David JONES, Liverpool (GB); Tom SUDLOW, Liverpool (GB); Kate FERRIE, Liverpool (GB); Samantha MURRAY, Liverpool (GB); Edward Ross SHENTON, Liverpool (GB); Hushmita MISTRY, Liverpool (GB); Fabian RIETH, Liverpool (GB)

(21) Appl. No.: 18/807,783

(22) Filed: Aug. 16, 2024

Related U.S. Application Data
(63) Continuation of application No. 16/999,248, filed on Aug. 21, 2020, now Pat. No. 11,749,540.
Application No. 16/999,248 is a continuation of application No. PCT/EP2019/054587, filed on Feb. 25, 2019.
Application No. PCT/EP2019/054587 is a continuation of application No. PCT/EP2019/054590, filed on Feb. 25, 2019.
Application No. PCT/EP2019/054590 is a continuation of application No. PCT/EP2019/054591, filed on Feb. 25, 2019.
Application No. PCT/EP2019/054591 is a continuation of application No. PCT/EP2019/054592, filed on Feb. 25, 2019.
Application No. PCT/EP2019/054592 is a continuation of application No. PCT/EP2019/054594, filed on Feb. 25, 2019.
Application No. PCT/EP2019/054594 is a continuation of application No. PCT/EP2019/054595, filed on Feb. 25, 2019.

(30) Foreign Application Priority Data
Feb. 26, 2018 (GB) 1803081.7
Feb. 26, 2018 (GB) 1803085.8
Feb. 26, 2018 (GB) 1803086.6
Feb. 26, 2018 (GB) 1803087.4
Feb. 26, 2018 (GB) 1803088.2
Feb. 26, 2018 (GB) 1803089.0
Feb. 26, 2018 (GB) 1803090.8
Feb. 26, 2018 (GB) 1803091.6
Feb. 26, 2018 (GB) 1803092.4
Feb. 26, 2018 (GB) 1803094.0
Feb. 26, 2018 (GB) 1803097.3
Feb. 26, 2018 (GB) 1803098.1

(51) Int. Cl. H01L 21/67; F16K 11/052; F16K 31/524

(52) U.S. Cl. CPC H01L 21/67126; F16K 11/052; F16K 31/52416; F16K 31/52441

(57) ABSTRACT

A heat not burn (HNB) consumable comprising a plant product formed into a planar slab (2) such that the consumable has a substantially rectangular transverse cross section. The planar slab of plant product may dosed with an aerosol former and may comprise a hydrophobic or liquid-impermeable outer coating. The consumable may further comprise a rectangular slab filter (4). The plant product may be formed into a cuboid brick (9) having a hollow core (10), with a core heating element in the hollow core.

### CROSS-REFERENCE TO RELATED APPLICATION(S)

This application is a continuation of U.S. application Ser. No. 16/999,298, filed Aug. 21, 2020, which is a continuation International Patent Application Numbers of PCT/EP2019/054587, PCT/EP2019/054590, PCT/EP2019/054591, PCT/EP2019/054592, PCT/EP2019/054594, PCT/EP2019/054595, PCT/EP2019/054596, PCT/EP2019/054597, PCT/EP2019/054598, PCT/EP2019/054599, PCT/EP2019/054601, and PCT/EP2019/054602, all filed Feb. 25, 2019, which collectively claim the benefit of the following Great Britain Patent Applications: 1803081.7, 1803085.8, 1803086.6, 1803087.4, 1803088.2, 1803089.0, 1803090.8, 1803091.6, 1803092.4, 1803094.0, 1803097.3, 1803098.1, all filed Feb. 26, 2018. All of these applications are incorporated herein by reference.

### TECHNICAL FIELD

The present disclosure relates to a consumable for a smoking substitute device. In particular, but not exclusively, to a heat not burn consumable comprising tobacco. It also relates to a heat not burn system comprising a consumable and a heating element, and a device for housing the system.

### BACKGROUND

The “smoking” of tobacco is generally considered to expose a smoker to potentially harmful substances. It is generally thought that a significant amount of the potentially harmful substances is generated through the heat caused by the burning and/or combustion of the tobacco and the constituents of the burnt tobacco in the tobacco smoke itself.

Combustion of organic material such as tobacco is known to produce tar and other potentially harmful by-products. There have been proposed various smoking substitute devices in order to avoid the smoking of tobacco.

Such substitute devices can form part of nicotine replacement therapies aimed at people who wish to stop smoking and overcome a dependence on nicotine.

Substitute devices may comprise electronic systems that permit a user to simulate the act of smoking by producing an aerosol that is drawn into the lungs through the mouth (inhaled) and then exhaled. The inhaled aerosol typically bears nicotine and/or flavourings without, or with fewer of, the odour and health risks associated with traditional smoking.

In general, substitute devices and systems are intended to provide a substitute for the rituals of smoking, whilst providing the user with a similar experience and satisfaction to those experienced with traditional smoking and tobacco products.

The popularity and use of smoking-substitute devices has grown rapidly in the past few years. Although originally marketed as an aid to assist habitual smokers wishing to quit tobacco smoking, consumers are increasingly viewing smoking substitute devices as desirable lifestyle accessories.

There are a number of different categories of substitute systems, each utilising a smoking substitute approach. A substitute approach corresponds to the manner in which the substitute system operates for a user.

An approach for a substitute system is the so-called “heat not burn” (HNB) approach in which tobacco, whether leaf tobacco or reconstituted tobacco, is heated or warmed to release vapour. The vapour may contain nicotine and/or flavour(s). In the HNB approach the intention is that the tobacco is not burned and does not undergo combustion.

In general, an HNB system includes a heating device and consumable. The consumable includes the tobacco material. The consumable is configured for engagement with the heating device. During use, heat is imparted to the tobacco material from a heating element of the heating device. Air flow through the tobacco material causes moisture in the tobacco material to be released as vapour. A first vapour may thus be formed from a carrier in the tobacco material, for example polyglycol (PG) or vegetable glycerine (VG). In addition, volatile compounds may also be released from the tobacco as a second vapour. The vapour(s) released from the tobacco are entrained in the airflow drawn through the tobacco.

As the vapours pass through the device (entrained in the airflow) from an inlet to a mouthpiece (outlet), the vapours cool and condense to form an aerosol for inhalation by the user. The aerosol contains the volatile compounds.

In HNB systems, heating as opposed to burning the tobacco material is believed to cause fewer, or smaller quantities, of the more harmful compounds ordinarily produced during smoking. Consequently, the HNB approach may reduce the odour and/or health risks that can arise through the burning, combustion and pyrolytic degradation of tobacco.

A first existing implementation of the HNB approach is the IQOS™ device from Philip Morris Ltd. The IQOS™ device uses a consumable element, including reconstituted tobacco contained within a metallic foil and paper wrapper. The consumable element is a cylindrical, rod-shaped element designed to resemble a traditional cigarette which is inserted into a heater device. The heater device has a thermally conductive heating blade which penetrates the reconstituted tobacco of the consumable element, when the consumable element is inserted into the heating device. Activation of the heating device heats the heating element, which, in turn, heats the tobacco in the consumable element. The heating of the tobacco causes it to release nicotine vapour and flavours which may be drawn through the mouthpiece by the user through inhalation.

A second existing implementation of the HNB approach is the device known as Glo™ from British American Tobacco. Glo™ also comprises a rod-shaped consumable similar in appearance to a traditional cigarette. The consumable element includes reconstituted tobacco in a paper wrapping which is heated in a heating device. When the consumable element is placed in the heating device, the tobacco is surrounded by a heating element. Activation of the heating device heats the heating element, which, in turn, heats the tobacco in the consumable element. The heating of the tobacco causes it to release nicotine vapour and flavours which may be drawn through the consumable element by the user through inhalation. The tobacco, when heated by the heating device, is configured to produce vapour when heated rather than when burned (as in a traditional cigarette). The tobacco may contain high levels of aerosol formers (carrier), such as vegetable glycerine (“VG”) or propylene glycol (“PG”).

Common to both the IQOS™ and Glo™ devices is uneven and incomplete heating of the tobacco, or possible burning of some regions of the tobacco.

Both devices also fail to conceal the residues which remain in the consumable after heating, these residues being both aesthetically unpleasing and also presenting a contamination risk to the user during removal of the consumable from the device.

Furthermore, the aerosol formers may leach from the consumable to satin and/or dampen the paper wrapping which is aesthetically unappealing and which can lead to transfer of the aerosol formers to contaminate the user.

Aspects and embodiments of the disclosure were devised with the foregoing in mind.

### SUMMARY

In a first aspect, there is provided a heat not burn (HNB) consumable comprising a plant product, wherein the plant product is formed into a planar slab such that the consumable has a substantially rectangular transverse cross section.

By providing the plant product as a planar slab (having a substantially rectangular transverse cross section) rather than as a cylindrical rod (having a substantially circular cross section), the plant product has a greater exposed surface area for contact with a heating element thus allowing quicker and more even heat transfer from the heating element to the plant product. In this manner, heating of the plant product can be effected using a heating element at a lower temperature (e.g. around 250° C.) which reduces the chances of burning of the plant product.

The planar slab preferably has a greater width and length than depth. The length and width may be equal but, preferably, the length is greater than the width such that the planar slab is a rectangular slab i.e. has substantially rectangular upper and lower surfaces. The length of the planar slab may be between 10 and 20 mm e.g. between 10 and 15 mm. The width of the planar slab may be between 7 and 18 mm e.g. between 8 and 14 mm or 10 and 12 mm. The depth of the planar slab may be between 1 and 8 mm, e.g. between 2 and 7 mm e.g. around 2 mm or around 6 mm.

The substantially rectangular transverse cross section is defined by a face having edges defining the width and depth i.e. the term “transverse cross section” is used to denote a cross section through the consumable perpendicular to the longitudinal axis/length of the planar slab/consumable. The planar slab has opposing longitudinal end faces which will each comprise a transverse cross section.

The planar slab of plant product may be dosed with an e-liquid either across its entirety or in selected portions. For example, the planar slab may be dosed with e-liquid at or proximal heating surfaces (e.g. the upper and lower surfaces of the planar slab) which, in use, are adjacent the heating element(s). The e-liquid may contain aerosol formers such as polyglycol (PG) and/or vegetable glycerine (VG). It may contain flavourings.

The planar slab of plant product may comprise a hydrophobic or liquid-impermeable outer coating (e.g. on at least the upper and lower surfaces) to prevent seepage or transfer of the e-liquid from the plant product.

The consumable may further comprise a filter as is typically known in the art. The filter may also be formed as a planar slab having a substantially rectangular transverse cross section. The filter preferably has a greater width and length than depth. The length and width may be equal but, preferably, the width is greater than the length. The filter typically has a shorter length than the planar slab of plant product. The depth of the filter may be between 4 and 8 mm, e.g. between 5 and 7 mm e.g. around 6 mm. The width of the filter may be between 7 and 18 mm e.g. between 8 and 14 mm or 10 and 12 mm.

The filter has a first longitudinal end face which faces and may abut a second longitudinal end face of the planar slab of plant product.

The filter may be a rectangular slab i.e. it may have substantially rectangular upper and lower surfaces. In other embodiments, the filter may have a second longitudinal end face (opposing the first longitudinal end face) comprising a curved/rounded (e.g. semi-circular) surface.

In some embodiments, the filter may comprise at least one liquid release member as described below.

Accordingly, there is provided a heat not burn (HNB) consumable comprising a plant product and a filter, wherein the filter comprises at least one liquid release member.

The liquid release member may contain an aerosol former such as vegetable glycerine and/or propylene glycol. By containing the aerosol former within a liquid release member that is configured to release the liquid (e.g. aerosol former) upon use, seepage of the liquid from the consumable to contaminate the user is avoided. Alternatively, the liquid release member can be a convenient way of introducing the e-liquid into the plant product during manufacture.

The plant product and/or the filter may be as described above and the liquid release member may positioned proximal the abutment between filter (e.g. at the first longitudinal end face of the filter) and the plant product so that upon release, the liquid can penetrate the plant product.

The liquid release member can comprise an envelope for containing the liquid. The envelope can be rigid and fragmentable under pressure (e.g. upon contact with the heating element). Alternatively, the envelope can be meltable upon application of heat.

The consumable (according to any embodiment herein) may comprise a spacer e.g. a paper spacer interposed between the filter and the plant product. The spacer may also be formed as a planar slab having a substantially rectangular transverse cross section. The spacer preferably has a greater width and length than depth. The length and width may be equal but, preferably, the width is greater than the length such that the planar slab is a rectangular slab i.e. has substantially rectangular upper and lower surfaces. The spacer typically has a shorter length than the planar slab of plant product and a longer length than the filter. The depth of the spacer may be between 4 and 8 mm, e.g. between 5 and 7 mm e.g. around 6 mm. The width of the spacer may be between 7 and 18 mm e.g. between 8 and 14 mm or 10 and 12 mm.

In some embodiments, the consumable comprises a single planar slab of plant product. In this case, the depth of the planar slab is preferably between 5 and 7 mm e.g. around 6 mm.

The planar slab of plant product may, in some of these embodiments, have a single heating surface (one of the upper and lower surfaces) for contact with a heating element (e.g. a planar heating element) or there may be opposing upper and lower heating surfaces each for contact with one of two heating elements (e.g. planar heating elements). The plant product is then heated externally and inwards from the upper and/or lower heating surfaces.

In other embodiments comprising a single planar slab, the plant product is heated internally and outwards (towards the upper and lower surfaces). To achieve this, there is provided a heat not burn (HNB) consumable comprising a plant product, wherein the plant product is formed into a cuboid brick having a hollow core (i.e. the planar slab is a hollow cuboid brick).

In use, the hollow core receives a heating element (i.e. by insertion of the heating element into the hollow core) which can contact the surfaces defining the recess thus allowing quicker and more even heat transfer from the heating element to the plant product. In this manner, heating of the plant product can be effected using a heating element at a lower temperature (e.g. around 250° C.) which reduces the chances of burning of the plant product.

As discussed above, the cuboid brick preferably has a greater width and length than depth. The length and width may be equal but, preferably, the length is greater than the width such that the cuboid brick has a substantially rectangular upper and lower outer surface. The depth of the cuboid brick may be between 4 and 8 mm, e.g. between 5 and 7 mm e.g. around 6 mm. The length of the cuboid brick may be between 10 and 20 mm e.g. between 10 and 15 mm. The width of the cuboid brick may be between 7 and 18 mm e.g. between 8 and 14 mm or 10 and 12 mm.

The cuboid brick has upper and lower outer surfaces spaced by opposing transverse outer surfaces. At least one of the upper/lower/transverse outer surfaces are at least partly coated with a hydrophobic/liquid impermeable coating.

The hollow core is defined by a cuboid recess extending in a length direction from the first longitudinal end face of the cuboid brick. The cuboid recess may extend from the first longitudinal end face to the opposing second longitudinal end face.

The cuboid recess is defined by upper and lower inner surfaces and opposing inner transverse surfaces. The cuboid recess may have a depth of between 0.5 and 2 mm e.g. around 1 mm. The cuboid recess may have a width of between 7 and 14 mm e.g. between 7 and 12 mm or 8 and 10 mm e.g. around 8 mm. The length of the cuboid recess may be between 10 and 20 mm e.g. between 10 and 15 mm.

The plant product at or proximal one or more of the upper/lower/transverse inner surfaces defining the cuboid recess may be dosed with e-liquid as described above.

The cuboid brick may be formed by extrusion.

In other embodiments, the consumable comprises a plurality of planar slabs of plant product e.g. two slabs of plant product. Where there are two planar slabs of plant product, the depth of each planar slab is preferably between 1 and 8 mm, e.g. between 2 and 5 mm e.g. around 2 mm.

Accordingly, the present disclosure also provides heat not burn (HNB) consumable comprising a plant product, wherein the plant product is formed into two planar slabs that are aligned and spaced from one another to define a planar recess therebetween such that the consumable has a substantially rectangular transverse cross section.

A heating element can be inserted into the planar recess so as to be releasably housed in the recess. In this way, heat can be transferred quickly and evenly to the plant product via the surfaces defining the planar recess.

Each planar slab may be as described above. The consumable may further comprise a filter and/or spacer as described above with each planar slab of plant product having a second longitudinal end face facing towards the filter/spacer.

In these embodiments, the planar slabs of plant product will each having an inner heating surface facing the planar recess and an opposing outer surface.

The plant product at or proximal the inner surface on one or both of the planar slabs of plant product may be dosed with e-liquid as described above.

The hydrophobic/liquid impermeable coating may be provided at the outer surface on one or both of the planar slabs of plant product.

The two planar slabs are preferably vertically and horizontally aligned. The planar recess is also vertically and horizontally aligned with the planar slabs.

It will be appreciated that in all embodiments described above, there is a constant depth of plant product between the surface that is heated (e.g. the upper and lower surfaces or the surfaces defining the cuboid/planar recess) and the opposing surface.

Therefore, in a second aspect, there is provided a heat not burn (HNB) consumable comprising a plant product wherein the plant product comprises a first substantially planar heating surface which, in use, faces a planar heating element and a second opposing surface, wherein the depth of the plant product between the first and second surfaces is substantially constant in a transverse (width) direction.

By providing the plant product with a substantially planar heating surface (for thermal contact with a heating element) the plant product has a greater exposed surface area for contact with a heating element thus for allowing quicker heating. The constant depth of plant product between the surfaces results in more even heat transfer from the heating element to the plant product. In this manner, heating of the plant product can be effected using a heating element at a lower temperature (e.g. around 250° C.) which reduces the chances of burning of the plant product.

In known cylindrical consumable products, the depth of plant product varies in a transverse direction with a greater depth at the axial centre.

The depth of the plant product between the first and second surfaces may be between 1 and 8 mm, e.g. between 2 and 7 mm e.g. around 2 mm or around 6 mm.

The plant product may be formed into least one planar slab or cuboid brick as described above for the first aspect.

The consumable may further comprise a filter and/or spacer as described above for the first aspect.

In some embodiments of the first/second aspects, the surfaces defining the cuboid or planar recess may be lined with a thermally conductive material. For example, the surface defining the recess may be at least 50% or 60% covered and preferably at least 70% or 80% or 90% covered. The recess may be fully lined with the thermally conductive material.

Accordingly, there is provided a heat not burn (HNB) consumable comprising a plant product wherein the plant product comprises a recess for receiving a heating element, wherein the recess is lined with a thermally conductive material.

The surfaces defining the recess may be at least 50% or 60% covered and preferably at least 70% or 80% or 90% covered. The recess may be fully lined with the thermally conductive material.

The thermally conductive material may be provided as a foil which may be textured e.g. dimpled.

The plant product e.g. the planar slab(s)/cuboid brick may comprise at least one channel extending into the plant product from either or both of the first and/or second longitudinal end faces of the plant product. The thermally conductive material may extend into the at least one channel. For example, the thermally conductive material may extend from the recess to the at least one channel over the first/second longitudinal end face of the plant product. This help increase heat transfer from the heating element within the recess into the plant product.

The consumable may comprise a further layer of the or a further thermoplastic material on an outer surface of the plant product opposing the recess.

The thermally conductive material or the thermally conductive material may be selected from the group consisting of: carbon or metal/metal alloy such as aluminum; brass; copper; gold; steel; silver; an alloy of one of more thereof; or a mixture of two or more thereof.

The consumable of the first or second aspects may further comprise a wrapping e.g. a paper or cardboard wrapping that encloses the upper/lower/outer surfaces and the transverse edges of the planar slab of plant product (and filter/spacer where present).

In embodiments where the plant product at least one channel extending into the plant product from the second longitudinal end face of the plant product (as described above), the wrapping (e.g. the cardboard wrapping may comprise a transverse extension which extends to cover a portion of the second longitudinal end face of the planar slab(s)/cuboid brick). The transverse extension may then comprise an inwardly-depending axial extension extending inwards into the at least one channel in the plant product.

The consumable of any embodiment described above may be contained within a housing, e.g. a housing as described below.

Accordingly, in a third aspect, there is provided a heat not burn (HNB) consumable comprising a plant product, wherein the plant product is at least partly (and preferably entirely) enclosed in a self-supporting housing.

The paper wrappers provided on the prior art consumables are relatively thin and flimsy. Whilst physically containing the plant product before and after use of the consumable, they do not effectively contain residues in the spent consumable and handling of the spent consumable can results in residue transfer to the user. By providing a more structurally robust (self-supporting) housing, the consumable becomes more akin to a cartridge or “pod” that effectively contains residue after use to protect a user from contamination.

The term “self-supporting” is intended to refer to a housing that does not flex or bend under its own weight.

Preferably, the housing is rigid or semi-rigid i.e. it is not easily flexible

At least a portion and preferably the whole of the housing has a wall thickness in the range of 0.8 to 8.0 mm, e.g. 1.5 to 5.0 mm.

The housing may have an inner surface facing the plant product wherein the inner surface is textured e.g. it may have a mesh texture.

The plant product may be as described above for the first/second aspect. The consumable may further comprise a filter and/or spacer as described above for the first aspect.

The housing may be formed of a biodegradable material such as cornstarch, bamboo, wood, palm, sugarcane, cardboard or paperboard, recycled or recyclable (thermoplastic) polymer material.

Accordingly, in some embodiments, the present disclosure provides a heat not burn (HNB) consumable comprising a plant product, wherein the plant product is at least partly (and preferably entirely) enclosed in a housing at least partly (and preferably entirely) formed of moulded pulp material e.g. natural fibre pulp material.

This provides a biodegradable, compostable and eco-friendly housing. The housing may be as described above e.g. it may be self-supporting and may have a wall thickness of 1.5 to 5.0 mm.

The housing may be at least partly formed of moulded tobacco cellulose pulp, wood pulp, bamboo pump, palm pulp or bagasse pulp. Bagasse pulp is most preferred.

The plant product may be as described above for the first/second aspect. The consumable may further comprise a filter and/or spacer as described above for the first aspect.

In some embodiments, the present disclosure provides a heat not burn (HNB) consumable comprising a plant product, wherein the plant product is at least partly (and preferably entirely) enclosed in a housing wherein the housing has a substantially rectangular transverse cross-sectional area.

Preferably, the main body of the housing is a hollow cuboid defining a cuboid recess. The plant product may be as described above and the cuboid recess is dimensioned to receive one or more planar slabs or a cuboid brick of plant product.

The housing may have an at least partly open first longitudinal end face. Alternatively, as discussed below, the first longitudinal end face may comprise a surface that at least partly obscures the plant product from view.

It may have an opposing second longitudinal end wall. The second longitudinal end wall may comprise at least one outlet/mouthpiece aperture. The second longitudinal end wall may comprise a curved/rounded (e.g. semi-circular) end wall.

The main body of the housing comprises an upper wall and lower wall spaced by opposing transverse side walls. At least one (and optionally both) of the opposing transverse side walls may comprise a longitudinally extending junction such that the housing can be opened to expose the cuboid recess.

The second longitudinal end surface/wall may also comprise a junction.

For example, both of the opposing transverse side walls and the second longitudinal end wall could comprise a respective junction such that the housing can be split into two opposing parts allowing for easy insertion during manufacture of the plant product (and filter/spacer where present).

Alternatively, one of the opposing transverse side walls and the second longitudinal end wall may contain the junctions and the other opposing transverse side wall may contain a longitudinally extending hinge portion such that the housing may be opened along the junctions by pivoting of the two opposing parts about the hinge portion. Where the consumable comprises two planar slabs, each planar slab may be mounted (e.g. glued) into a respective part (e.g. half) of the housing such that when the two opposing parts are brought together the planar slabs are spaced from one another to define the planar recess therebetween (as discussed above).

The housing may be as described above e.g. it may be self-supporting and/or it may be formed of biodegradable e.g. moulded pulp material.

The consumable may further comprise a filter and/or spacer as described above for the first aspect.

As discussed above, the second longitudinal end of the housing comprises a second longitudinal end wall. The filter is typically provided adjacent e.g. with its second longitudinal end face abutting this longitudinal end wall of the housing. Thus the second longitudinal end wall conceals the filter from the user.

Accordingly, there is provided a heat not burn (HNB) consumable comprising a plant product and a filter, wherein the consumable further comprises a housing having a first longitudinal end face and a second longitudinal end face, wherein the second longitudinal end face comprises a second longitudinal end wall that at least partly (and preferably completely) obscures the filter from view by a user.

By concealing the filter from view, the user is not exposed to the residues remaining in the filter/consumable after use thus improving the aesthetic appeal of the consumable after use and avoiding transfer of residue to the user.

Similarly, and as is discussed above, the opposing first longitudinal end face may comprise a surface that at least partly obscures the plant product from view. As is also discussed below, to at least partly obscure the plant product from view, the first longitudinal end face of the housing may additionally or alternatively comprise a pierceable or peelable membrane such as a metallic foil or plastic membrane. The membrane may be mounted across the entire open first longitudinal end face of the housing or it may be mounted on the first longitudinal end wall across the aperture. The membrane seals the first longitudinal end face prior to use and is pierced to mount the consumable on the heating element.

The second longitudinal end face may be as described above. In this respect, the second longitudinal end wall may comprise at least one outlet/mouthpiece aperture. The second longitudinal end wall may comprise a curved/rounded (e.g. semi-circular) end wall.

The housing may be as described above e.g. it may be self-supporting and/or it may be formed of biodegradable e.g. moulded pulp material and/or it may have the shape described above.

The plant product and filter (and spacer where present) may be as described above for the first/second aspect.

Although the second longitudinal end wall may comprise one or more outlet(s)/mouthpiece aperture(s), this/these are typically small enough that visual inspection of the filter is significantly impeded compared to the prior art consumable where the end face of the filter is completely exposed. Thus whilst the second longitudinal wall may be discontinuous, it preferably covers (e.g. overlies or abuts) at least 20% e.g. at least 30 or 40% and preferably at least 50%, e.g. at least 70% such as at least 80% or 90% of the surface area of the second longitudinal end face of the filter.

As discussed above, the housing may have an open first longitudinal end face.

Alternatively, there is provided a heat not burn (HNB) consumable comprising a plant product, wherein the consumable further comprises a housing having a first longitudinal end face, wherein the first longitudinal end face comprises a surface that at least partly obscures the plant product from view by a user at least prior to use.

The first longitudinal end face of the housing may comprise a first longitudinal end wall for at least partly overlying (e.g. abutting) a longitudinal end face of the plant product. The first longitudinal end wall may comprise an aperture (into which the heating element can be inserted).

The first longitudinal end wall may be a perimeter wall i.e. it may extend only around one or more of the edges of the first longitudinal end face of the housing. For example, it may extend around all edges to form a frame defining the aperture (into which the heating element can be inserted). The aperture may be dimensioned to match the dimensions of the cuboid recess when the plant product is formed as a cuboid brick.

In other embodiments, the first longitudinal end wall of the housing may extend along the upper and lower edges to form rails defining the aperture therebetween. The aperture may be dimensioned to match the dimensions of the planar recess when the plant product is formed as two planar slabs.

In embodiments where the plant product comprises at least one channel extending into the plant product from the first longitudinal end face of the plant product (as described above), the first longitudinal end wall may comprise an inwardly-depending axial extension, extending inwards into the at least one channel in the plant product.

In some embodiments, the first longitudinal end face of the housing may additionally or alternatively comprise a pierceable or peelable membrane such as a metallic foil or plastic membrane.

The membrane may be mounted across the entire open first longitudinal end face of the housing or it may be mounted on the first longitudinal end wall across the aperture.

The membrane seals the first longitudinal end face prior to use and is pierced to mount the consumable on the heating element.

The housing may be as described above e.g. it may be self-supporting and/or it may be formed of biodegradable e.g. moulded pulp material and/or it may have the shape described above and/or it may have a second longitudinal end face adapted to conceal a filter.

The plant product (and filter/spacer where present) may be as described above for the first/second aspect.

In any of the aspects described above, the plant product may be derived or obtained from at least one plant from which an active substance may be aerosolized into a breathable fluid stream for inhalation by a user. Suitable plant products include Amaranthus dubius, Arctostaphylos uva-ursi (Bearberry), Argemone mexicana, Arnica, Artemisia vulgaris, Yellow Tees, Calea zacatechichi, Canavalia maritima (Baybean), Cecropia mexicana (Guamura), Cestrum nocturnum, Cynoglossum virginianum (wild comfrey), Cytisus scoparius, Damiana, Entada rheedii, Eschscholzia californica (California Poppy), Fittonia albivenis, Hippobroma longiflora, Humulus japonica (Japanese Hops), Humulus lupulus (Hops), Lactuca virosa (Lettuce Opium), Laggera alata, Leonotis leonurus, Leonurus cardiaca (Motherwort), Leonurus sibiricus (Honeyweed), Lobelia cardinalis, Lobelia inflata (Indian-tobacco), Lobelia siphilitica, Nepeta cataria (Catnip), Nicotiana species (Tobacco), Nymphaea alba (White Lily), Nymphaea caerulea (Blue Lily), Opium poppy, Passiflora incarnata (Passionflower), Pedicularis densiflora (Indian Warrior), Pedicularis groenlandica (Elephant's Head), Salvia divinorum, Salvia dorrii (Tobacco Sage), Salvia species (Sage), Scutellaria galericulata, Scutellaria lateriflora, Scutellaria nana, Scutellaria species (Skullcap), Sida acuta (Wireweed), Sida rhombifolia, Silene capensis, Syzygium aromaticum (Clove), Tagetes lucida (Mexican Tarragon), Tarchonanthus camphoratus, Turnera diffusa (Damiana), Verbascum (Mullein), Zornia latifolia (Maconha Brava) together with any combinations, functional equivalents to, and/or synthetic alternatives of the foregoing.

In some embodiments, the plant product may be reconstituted tobacco.

As referred to herein, the term “active substance” denotes a chemical and/or physiologically active species, or combination or mixture of such chemical and/or physiologically species, that are intended to be aerosolized, and that may provide the user with a recreational and/or medicinal effect when a breathable fluid stream comprising the aerosol is inhaled by a user. Suitable chemical and/or physiologically active species includes the group consisting of: nicotine, cocaine, caffeine, opiates and opioids, cathine and cathinone, kavalactones, myristicin, beta-carboline alkaloids, salvinorin A together with any combinations, functional equivalents to, and/or synthetic alternatives of the foregoing.

The consumable of any one of the first to third aspects may be coupled with a heating element in a heat not burn (HNB) system.

Accordingly in a fourth aspect, there is provided a heat not burn (HNB) system comprising:
a heat not burn consumable according to any one or more of the first to third aspects; and
at least one heating element,

wherein the consumable is engageable with the heating element such that the heating element faces (e.g. abuts (directly or indirectly) or overlies) a heating surface of the consumable.

In some embodiments, the plant product is a planar slab having an upper surface and a lower surface and the at least one heating element is a first heating element for facing/abutting the upper or lower surface.

The system may comprise a second heating element which, when the consumable is engaged, faces/abuts/overlies the other of the upper and lower surface.

As is discussed further below, the or each heating element may form part of a heating device for use with the consumable. The consumable may be (releasably) engaged with the or each heating element of the device for heating by the or each heating element. Once consumed the consumable may be released from the or each heating element and a further consumable may subsequently be (releasably) engaged with the or each heating element of the device for heating.

In some embodiments where the plant product is formed into two planar slabs that are aligned and spaced from one another to define a planar recess therebetween, the at least one heating element is a core heating element and the core heating element is received/receivable in the planar recess.

In other embodiments where the plant product is formed into a cuboid brick having a hollow core, the at least one heating element is a core heating element, wherein the core heating element is received/receivable in the cuboid recess.

Where the consumable comprises a housing as described above in the third aspect, the at least one heating element (which may be a first, second or core heating element as described above), is at least partially (and optionally fully) enclosed within the housing when the consumable is engaged.

The at least one/first/second/core heating element is/are received/receivable in the housing through the first longitudinal end face of the housing. Where there is an end wall defining an aperture at the first longitudinal end face of the housing as described above, the at least one/first/second/core heating element is/are received/receivable in the housing through the aperture. Where there is a membrane sealing the first longitudinal end face of the housing or the aperture, the membrane is removed or pierced to allow insertion of the at least one/first/second/core heating element into the housing.

The at least one heating element (e.g. first/second/core heating element) is/are preferably a planar heating element i.e. has at least one and preferably two opposing planar surface(s).

The at least one heating element (e.g. first/second/core heating element) may be formed as a planar heating slab. It may have a greater width and length than depth. The length and width may be equal but, preferably, the length is greater than the width such that the planar heating slab is a rectangular slab i.e. has a substantially rectangular upper and lower planar surface. The length of the planar heating slab may be between 10 and 20 mm e.g. between 10 and 15 mm. The width of the planar slab may be between 7 and 14 mm e.g. between 7 and 12 mm or 7 and 10 mm e.g. around 8 mm. The depth of the planar heating slab may be between 0.5 and 2 mm, e.g. around 1 mm.

The at least one heating element (e.g. first/second/core heating element) may be a ceramic heating element.

In a fifth aspect, the present disclosure provides a heat not burn (HNB) device comprising:
a heat not burn system according to the fourth aspect; and
a device housing,

wherein the device housing at least partly (and preferably fully) encloses the at least one (first/second/core) heating element(s).

The consumable (which is as described for the first, second or third aspect) is insertable into the device housing for engagement (i.e. releasable engagement) with the at least one/first/second/core heating element(s). Where the consumable comprises a housing as described for the third aspect, the consumable is inserted with the second longitudinal end wall of the housing protruding from the device housing.

There is also provided a heat not burn (HNB) device comprising:
a device housing; and
at least one heating element, the at least one heating element being housed within a chamber at a first longitudinal end of the device housing, the device housing have a first longitudinal end face defining an aperture in communication with said chamber,

wherein the device further comprises a sealing plate movable from a first position in which the aperture is open to a second position in which the aperture is at least partially sealed by the sealing plate.

The sealing plate may be slidable (e.g. slidable in an axial direction) from the first position to the second position.

In the first position, the sealing plate forms a base of the chamber with the at least one heating element extending towards the aperture through the sealing plate. The sealing plate may be an apertured plate, so that as the sealing plate moves from the first to the second position, the at least one heating element passes through the aperture.

The device housing may comprise at least one channel and the sealing plate may comprise at least one transverse tab extending from the sealing plate through the channel to rest on an exterior of the device housing. The device housing may comprise two opposing channels and the sealing plate may comprise two opposing transverse tabs. The transverse tab(s) may be used to manually move the sealing plate between the first and second positions.

The device housing may have a substantially rectangular transverse cross-section.

The device is adapted to receive a consumable (which is as described for the first, second or third aspect) and which is insertable into the device housing for engagement with the at least one heating element (which may be a first/second/core heating element as described above). Where the consumable comprises a housing as described for the third aspect, the consumable is inserted with the second longitudinal end wall of the housing protruding from the device housing.

The consumable is inserted when the sealing plate is in its first position. After use, the sealing plate is moved to its second position which forces the consumable from the chamber and, ultimately blocks the aperture at the first longitudinal end face of the device housing so that the user is prevent from contacting the hot heating element.

The device may further comprise a PCB connected to the heating element(s) for controlling the temperature of the heating element(s). It may further comprise a battery e.g. a recyclable battery such as a 2000 mAh battery.

The disclosure includes the combination of the aspects and preferred features described except where such a combination is clearly impermissible or expressly avoided.

### BRIEF DESCRIPTION OF THE DRAWINGS

So that the disclosure may be more readily understood, and so that further features thereof may be appreciated, embodiments and experiments illustrating the principles of the disclosure will now be described by way of example with reference to the accompanying figures in which:

FIG. 1 shows a first embodiment of a consumable comprising a planar slab of plant product;

FIG. 2 shows cuboid brick of plant product;

FIG. 3 shows a housing for a consumable;

FIG. 4 shows a second embodiment of a consumable comprising a planar slab of plant product;

FIGS. 5a-5c shows a third embodiment of a consumable;

FIGS. 6a and 6b show a fourth embodiment of a consumable;

FIG. 7 shows the fourth embodiment with a core heating element inserted;

FIG. 8 shows a lateral cross section through the third embodiment with a core heating element inserted;

FIGS. 9-11 show a device according to an embodiment;

FIG. 12 shows a fifth embodiment of a consumable;

FIG. 13 shows a longitudinal cross section through a sixth embodiment of a consumable; and

FIG. 14 shows a longitudinal cross section through a seventh embodiment of a consumable.

### DETAILED DESCRIPTION

Aspects and embodiments of the disclosure will now be discussed with reference to the accompanying figures. Further aspects and embodiments will be apparent to those skilled in the art.

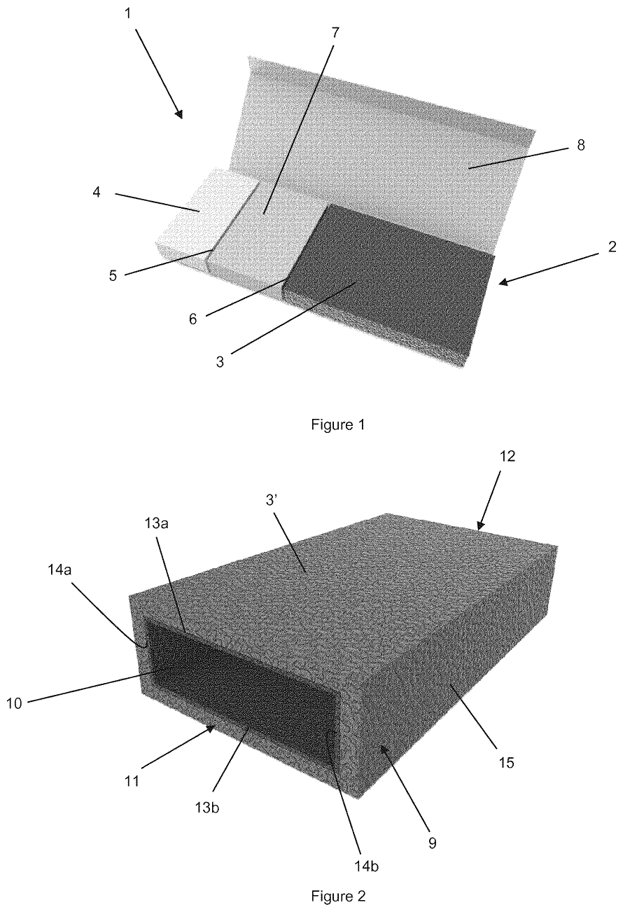

FIG. 1 shows a perspective view of a first embodiment of a heat not burn (HNB) consumable 1 comprising a planar slab 2 of reconstituted tobacco such that the consumable has a substantially rectangular transverse cross section.

By providing the reconstituted tobacco as a planar slab (having a substantially rectangular transverse cross section) rather than as a cylindrical rod (having a substantially circular cross section), the reconstituted tobacco has a greater exposed surface area for contact with a heating element thus allowing quicker and more even heat transfer from the heating element to the reconstituted tobacco. In this manner, heating of the reconstituted tobacco can be effected using a heating element at a lower temperature (e.g. around 250° C.) which reduces the chances of burning of the reconstituted tobacco.

The planar slab 2 has a substantially rectangular upper surface 3 having a length of around 12 mm, a width of around 8 mm and a depth of around 6 mm.

The consumable further comprises a filter 4. The filter is also formed as a planar slab having a substantially rectangular transverse cross section. The filter typically has a width of around 8 mm, a depth of around 6 mm and a length of around 3 mm.

The filter has a first longitudinal end face 5 which faces a second longitudinal end face 6 of the planar slab 2 of reconstituted tobacco.

The consumable 1 further comprises a paper spacer 7 interposed between the filter 4 and the plant product 2. The spacer typically has a width of around 8 mm, a depth of around 6 mm and a length of around 5 mm.

The consumable 1 further comprises a paper wrapper 8 which is shown open in FIG. 1 but which is wrapped around to fully enclose the upper surfaces and the opposing transverse faces of the consumable.

This consumable 1 of FIG. 1 may be heated using a first heating element in abutment with the upper surface 3 and/or a second heating element in abutment with the lower surface.

The planar slab 2 is then heated and externally and inwards from the upper and/or lower surfaces.

FIG. 2 shows a portion of reconstituted tobacco extruded into a cuboid brick 9. The cuboid brick has an upper outer surface 3′ and a lower outer surface (not visible) spaced by opposing transverse outer surfaces 15 (only one visible). These outer surfaces are coated with a hydrophobic/liquid impermeable coating.

The length of the cuboid brick is typically around 12 mm, with a depth of around 6 mm and width of around 10 mm.

The cuboid brick 9 has a hollow core defined by a cuboid recess 10 extending in a length direction from the first longitudinal end face 11 of the cuboid brick 9 to the opposing second longitudinal end face 12.

The cuboid recess 10 is defined by upper and lower inner surfaces 13a, 13b and opposing inner transverse surfaces 14a, 14b. The cuboid recess has a depth of around 1 mm, a width of around 8 mm and a length of around 12 mm.

The reconstituted tobacco at or proximal one or more of the upper/lower/transverse inner surfaces 13a, 13b, 14a, 14c defining the cuboid recess 10 may be dosed with an e-liquid which may contain aerosol formers such as polyglycol (PG) and/or vegetable glycerine (VG).

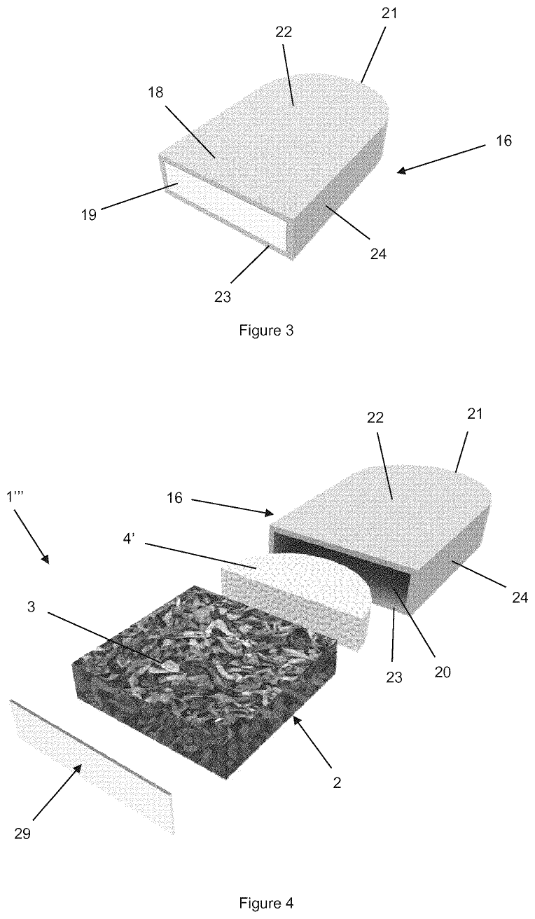

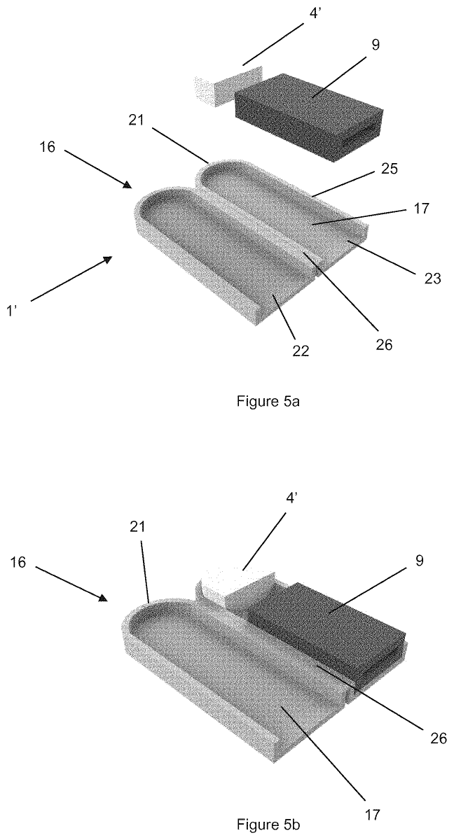

As can be seen in FIGS. 5a-5b, the cuboid brick 9 can be inserted and glued into a substantially rigid, self-supporting housing 16 having walls of a uniform thickness of around 2 mm formed of moulded bagasse pulp to form the consumable 1′. The housing 16 has a textured e.g. meshed inner surface 17 facing the reconstituted tobacco. The outer surface 18 (visible in FIG. 3) of the housing 16 is substantially smooth.

As also seen in FIG. 3, the main body of the housing 16 is a hollow cuboid defining a cuboid recess 20 which is dimensioned to receive the cuboid brick 9 of reconstituted tobacco.

The housing 16 has an open first longitudinal end face 19 having a rectangular transverse cross-section. It has a rounded opposing second longitudinal end wall 21 which has at least one mouthpiece aperture (not visible).

The consumable 1′ has a filter 4′ having a rounded second longitudinal end face for abutment with the inside surface of the second longitudinal end wall 21 of the housing 16.

The second longitudinal end wall 21 at least partly (and preferably completely) obscures the filter 4′ from view by a user.

By concealing the filter 4′ from view, the user is not exposed to the residues remaining in the filter 4′/consumable 1′ after use thus improving the aesthetic appeal of the consumable after use and avoiding transfer of residue to the user.

The main body of the housing 16 comprises an upper wall 22 and lower wall 23 spaced by opposing transverse side walls 24. One of the opposing transverse side walls 24 comprises a longitudinally extending junction 25 and the second longitudinal end wall 21 also comprises a junction such that the housing can be opened to expose the cuboid recess as shown in FIGS. 5a-5c.

The other opposing side wall 24′ comprises a longitudinally extending hinge portion 26 such that the housing may be opened along the junctions by pivoting of the upper wall 22 and lower wall 23 about the hinge portion 26.

In this way, the cuboid brick 9 and the filter 4′ can be fitted (and glued) into the opened housing 16 and then the housing closed (by pivoting about the hinge portion 26 as shown in FIG. 5c). The junctions can be sealed e.g. with glue.

The closed housing 16 has the shape shown in FIG. 3 and, with such a housing 16, the consumable 1′ becomes more akin to a cartridge or “pod” that effectively contains residue after use to protect a user from contamination.

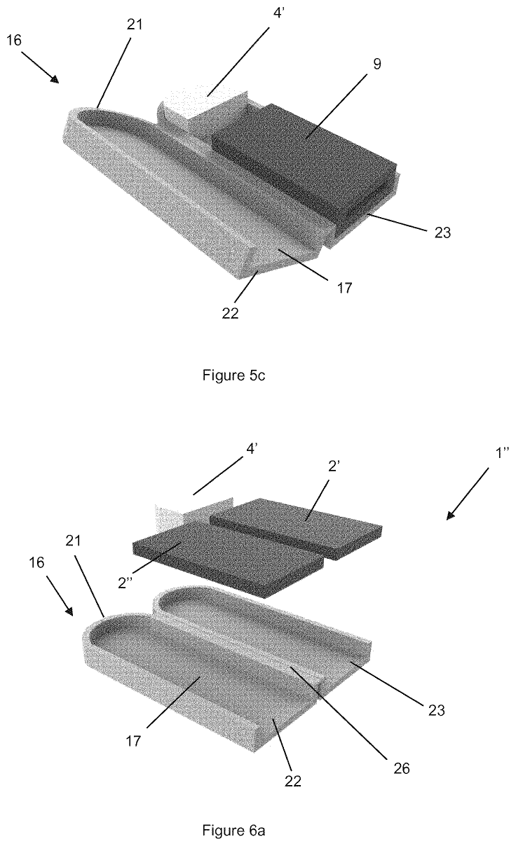

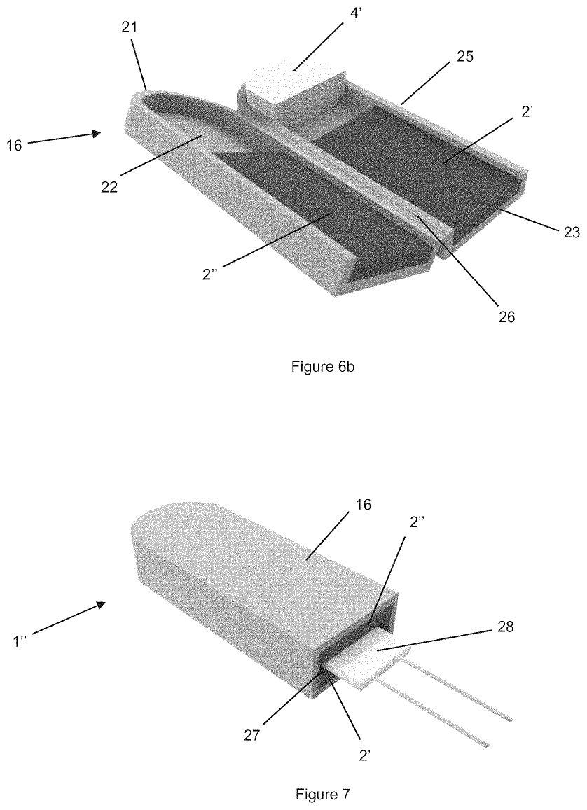

FIGS. 6a-6b shown another embodiment in which the consumable 1″ comprises two planar slabs 2′, 2″ of reconstituted tobacco, each having a depth of around 2 mm, a length of around 12 mm and a width of around 10 mm.

The two planar slabs 2′, 2″ are vertically and horizontally aligned and spaced from one another to define a planar recess 27 (visible in FIG. 7). The housing is as described previously and the two planar slabs 2′, 2″ are each glued into a respective half of the housing (see FIG. 6b) before closing the housing by pivoting along the hinge portion 26 to form the planar recess 27. The tobacco at or proximal the inner surface (facing the planar recess 27) on one or both of the planar slabs 2′, 2″ is dosed with e-liquid as described above. The junctions around the housing are sealed using glue.

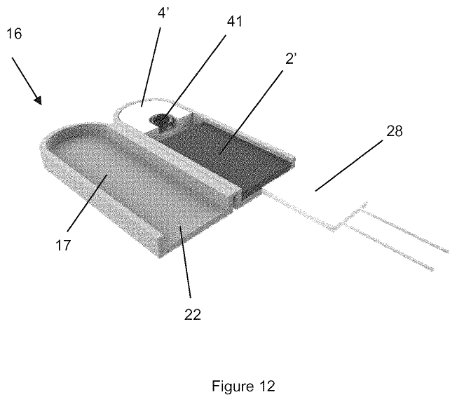

FIG. 12 shows a variation (one planar slab omitted from view) where the filter 4′ (shown in cross-section) comprises a liquid release member 41 containing an aerosol former such as vegetable glycerine and/or propylene glycol at its first longitudinal end face. The release member 41 is configured to release the aerosol former either during manufacture (e.g. by providing a crushable envelope) or during use (e.g. by providing an envelope that is breakable upon abutment with the heating element 28 or that melts during heating) so that upon release, the aerosol former can penetrate the plant product.

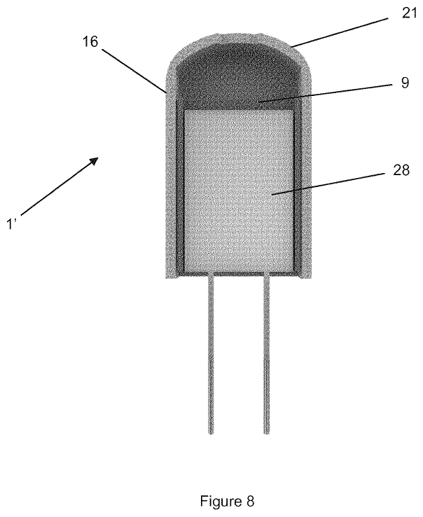

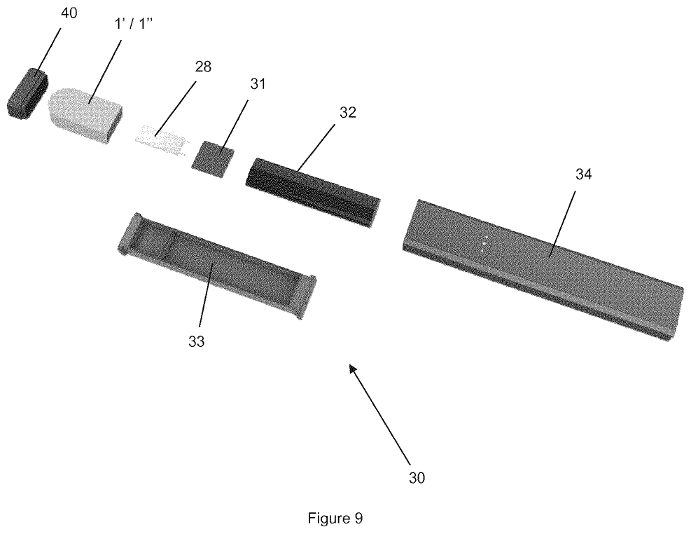

The closed housing 16 is seen in FIG. 7 with a planar, ceramic heating element 28 inserted into the planar recess 27. FIG. 8 shows a longitudinal cross section of the housing 16 containing the cuboid brick 9 of reconstituted tobacco.

As can be seen, when inserted into the recess 27, the heating element 28 can contact the surfaces of the cuboid recess 10 or planar recess 27 thus allowing quicker heating. It can also be seen that, in all embodiments, the depth of the reconstituted tobacco between the heating surface(s) and the opposing surfaces is substantially constant in the width direction which results in a more even heat transfer from the heating element 28 to the reconstituted tobacco. In this manner, heating of the tobacco can be effected using a heating element 28 at a lower temperature (e.g. around 250° C.) which reduces the chances of burning of the plant product.

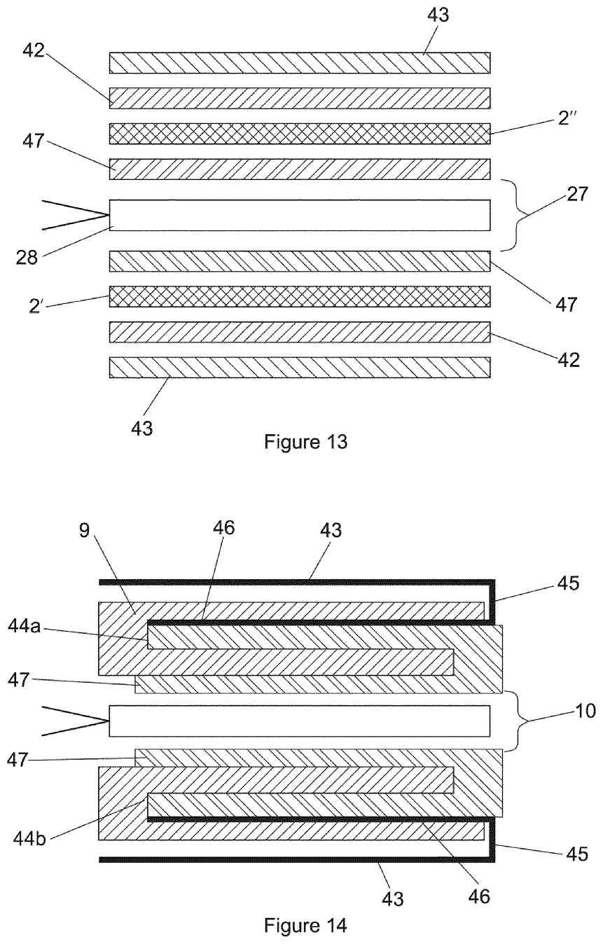

FIGS. 13 and 14 show further embodiments where the planar recess 27 or cuboid recess 10 is fully lined with a thermally conductive material such as aluminum foil 47. The aluminum foil fully lines the recess 10, 27 and overlies the plant product which may be in the form of two planar slabs 2, 2′ (as shown in FIG. 11) or may be a cuboid brick 9 (as shown in FIG. 12).

In the embodiment shown in FIG. 13, the opposing outer surfaces of the planar slabs 2′, 2″ are further lined with a dimpled foil 42 (which is liquid impermeable). The plant product and foil layers 47, 42 are enclosed with cardboard wrapper 43 (although it may also be formed of moulded pulp, e.g. moulded bagasse pulp).

The heating element 28 is received within the planar recess 27 and the aluminum foil 47 increases heat transfer to the plant product. The dimpled foil 42 forms a liquid impermeable barrier to prevent seepage of any e-liquid dosed into the plant product into the cardboard wrapper, the dimples acting to increase air flow through the consumable upon inhalation by the user.

In FIG. 14, the aluminum foil 47 fully lines the cuboid recess 10 and then extends over the second longitudinal end face 12 of the cuboid brick and axially into channels 44a, 44b formed within the second longitudinal end face 12. Thus the aluminum foil partly covers the second longitudinal end face 12 of the cuboid brick.

The cuboid brick 9 and foil layers 47, 42 are enclosed with a cardboard wrapper 43 (although it may also be formed of moulded pulp, e.g. moulded bagasse pulp). The wrapper comprises a transverse extension 45 which extends to cover a portion of the second longitudinal end face 19 of the cuboid brick 9. The transverse extension 45 comprises an inwardly-depending axial extension 46 extending inwards into the channels 44a, 44b in the plant product in abutment with the aluminum foil 47.

The heating element 28 is received within the cuboid recess 10 and the aluminum foil 47 increases heat transfer to the plant product.

A further embodiment of a consumable 1′″ is shown in FIG. 4 where the housing 16 and filter 4′ are as previously described. The reconstituted tobacco is formed as single planar slab 2 having a substantially rectangular upper surface 3 having a length of around 12 mm, a width of around 8 mm and a depth of around 6 mm.

The first longitudinal end face 19 of the housing 16 is provided with a pierceable or peelable membrane such as a metallic foil or plastic membrane 29. Such a membrane may be provided on any of the previously described embodiments and is provided to at least partly obscure the reconstituted tobacco from view by a user prior to use. When the consumable 1′″ is used, the membrane can be removed or pierced to insert the heating element 28.

For this embodiment, the heating element could be a heating blade that pierces the planar slab 2.

FIG. 9 shows a heat not burn (HNB) device 30 comprising the heating element 28 which is mounted on and controlled by a PCB 31 connected to a battery 32, the PCB 31 and battery 32 being housed within an electrical sleeve 33. In turn electrical sleeve 33 and heating element 28 are housed within (and fully enclosed by) a device housing 34. The device housing 34 has a chamber 35 at its first longitudinal end which has an aperture at its first longitudinal end face and which houses the heating element 28.

The consumable 1′/1″ is insertable into the chamber 35 within the device housing 34 such that the heating element 28 is received in the housing 16 (e.g. within the planar recess 26 or cuboid recess 10 within the reconstituted tobacco) via the first longitudinal end face 19 of the housing 16. The second longitudinal end wall 21 of the housing 16 protrudes from the device housing.

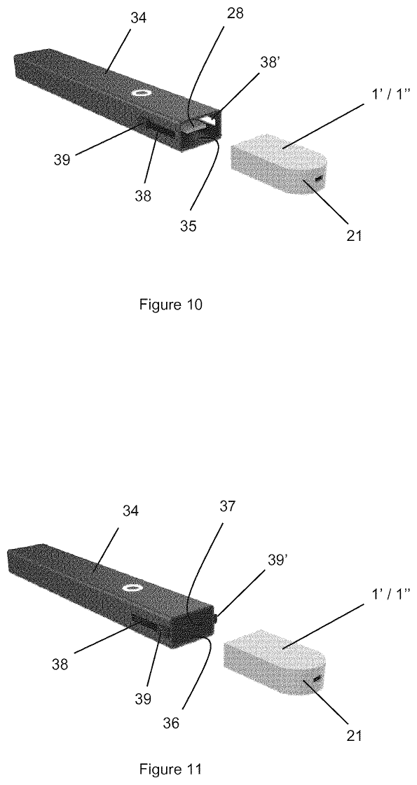

The device further comprises a sealing plate 36 movable (slidable in a axial direction) from a first position (shown in FIG. 10) in which the aperture at the first longitudinal end face of the device housing 34 is open to a second position (shown in FIG. 11) in which the aperture is at least partially sealed by the sealing plate 36.

In the first position, the sealing plate 36 forms a base of the chamber 35 with the heating element 28 extending towards the aperture through the sealing plate 36. The sealing plate 36 has a slit 37, so that as it moves from the first to the second position, the heating element 28 passes through the slit.

The device housing 34 has two opposing channels 38, 38′ and the sealing plate 36 comprises two opposing transverse tabs 39, 39′ extending from the sealing plate 36 through the channels 38, 38′ to rest on an exterior of the device housing 34. The transverse tabs 39, 39′ may be used to manually move the sealing plate 36 between the first and second positions.

The consumable 1′/1″ is inserted when the sealing plate 36 is in its first position. The heating element 28 lies within the cuboid recess 10 or the planar recess 27 and the user activates the heating element e.g. by an actuator button located on the device housing 34. The device housing may also comprise an indicator showing when the heating element 28 had reached the correct temperature (250° C.).

The user then places the second longitudinal end wall 21 of the consumable 1′/1″ into their mouth and draws on the consumable in order to inhale and aerosol containing nicotine.

After use, the sealing plate 36 is moved to its second position which forces the consumable 1′/1″ from the chamber 35 and ultimately blocks the aperture at the first longitudinal end face of the device housing 34 so that the user is prevent from contacting the hot heating element 28.

The device 30 may further comprise a cap 40 e.g. a magnetic cap for sealing the aperture at the first longitudinal end face of the device housing e.g. when the device is not in use for an extended period. The cap 40 may have a recess on its underside such that the aperture can be sealed with a consumable 1′, 1″ in situ.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the scope of the invention.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

We claim:

1. A heat-not-burn device, comprising:
a first housing containing a battery electrically connected to a planar heating element in a chamber at a first end of the housing;
a second housing containing a heat not burn consumable comprising a plant product formed into a cuboid brick; and
the planar heating element in contact with at least one surface of the cuboid brick and configured to heat the cuboid brick via heat penetrating from the outside of the cuboid brick towards the inside of the cuboid brick.

2. The heat not burn device of claim 1, wherein the second housing has a first longitudinal end comprising a surface that at least partly obscured the plant product from view.

3. The heat not burn device of claim 2, further comprising a filter having at least one liquid release member containing an aerosol former, the aerosol former penetrating the plant product when released.

4. The heat not burn device of claim 3, wherein a second longitudinal end of the second housing has a curvature and the filter has a matching curvature.

5. The heat not burn device of claim 2, wherein the second housing has a textured inner surface facing the plant product.

6. The heat not burn device of claim 2, further comprising a membrane on the first longitudinal end of the second housing.

7. The heat not burn device of claim 1, wherein the at least one surface is dosed with an e-liquid containing an aerosol former.

8. The heat not burn device of claim 1, further including a thermally conductive material on the at least one surface of the cuboid brick.

9. The heat not burn device of claim 1, further comprising a hydrophobic or liquid-impermeable coating on exterior surfaces of the cuboid brick.

10. The heat not burn device of claim 1, wherein the second housing comprises first half pivotally attached to a second half by a hinge.

11. A heat not burn consumable, comprising:
a plant product formed into a cuboid brick having a hollow core;
the hollow core defined by a cuboid recess extending in a length direction from a first end towards a second end of the cuboid brick;
the cuboid recess configured to releasably receive a planar heating element, with the planar heating element in contact with interior surfaces of the cuboid brick.

12. The heat not burn consumable of claim 11, further comprising a self-supporting cuboid housing around the cuboid brick, the cuboid housing having an at least partly open first longitudinal end, and a hollow cuboid main body.

13. The heat not burn consumable of claim 11, further comprising a filter having at least one liquid release member containing an aerosol former, the aerosol former penetrating the plant product when released, wherein a second longitudinal end of the self-supporting housing has a curvature and the filter has a matching curvature.

14. The heat not burn consumable of claim 11, wherein the self-supporting housing has a textured inner surface facing the plant product.

15. The heat not burn consumable of claim 11, further comprising a pierceable membrane on the first longitudinal end face of the self-supporting housing.

16. The heat not burn consumable of claim 11, wherein the cuboid recess is lined with a thermally conductive material.

17. The heat not burn consumable of claim 11, further comprising a hydrophobic or liquid-impermeable coating on exterior surfaces of the cuboid brick.

18. A heat-not-burn device, comprising:
a first housing containing a battery electrically connected to a planar heating element in a chamber at a first end of the housing;
a second housing containing a heat not burn consumable comprising a plant product formed into a cuboid brick having a hollow core, the hollow core defined by a cuboid recess extending in a length direction from a first end face towards a second end face of the cuboid brick;
the planar heating element inserted into the cuboid recess, and the planar heating element contacting upper and lower internal surfaces of the cuboid brick.

19. The heat-not-burn device of claim 18 further comprising a plate in the chamber movable from a first position wherein the plate is withdrawn from the first end of the first housing, to a second position wherein the plate is advanced towards the first end of the housing to least partially close off the first end of the first housing.

20. The heat-not-burn device of claim 19 wherein the heating element extends through an opening in the plate.
